(19) United States
(12) Patent Application Publication
(10) Pub. No.: US 2008/0239660 A1
(43) Pub. Date: Oct. 2, 2008

(54) Flux precoated solder preform for thermal interface material

(76) Inventors: Lateef Mustapha, Oro Valley, AZ (US); Carl Deppisch, Chandler, AZ (US); Anna Prakash, Chandler, AZ (US); Sai Jayaraman, Chandler, AZ (US); Mike Reiter, Gilbert, AZ (US)

Correspondence Address: CAVEN & AGHEVLI;c/o INTELLEVATE, LLC, P.O. BOX 52050, MINNEAPOLIS, MN, 55402, US

(21) Appl. No.: 11/731,758

(22) Filed: Mar. 29, 2007

(51) Int. Cl. H05K 7/20

(52) U.S. Cl. 361/688; 361/699

(57) ABSTRACT

In one embodiment, an apparatus comprises a semiconductor device, a heat dissipation assembly, and a thermal interface material disposed between the semiconductor device and the heat dissipation assembly, wherein the thermal interface layer comprises a pre-coated flux material.

### BACKGROUND

The subject matter described herein relates generally to the field of electronic devices and more particularly to flux precoated solder preform for thermal interface materials.

Electronic components, including integrated circuits, may be assembled into component packages by physically and electrically coupling them to a substrate. During operation, the component package may generate heat that can be dissipated to help maintain the circuitry at a desired temperature. Heat sinks, heat spreaders, integrated heat spreaders (IHS) and other heat dissipating elements may be attached to the package via a suitable thermal interface material.

Semiconductor manufacturing processes may involve spraying liquid flux material onto the backside of a die by a flux dispenser followed by a solder thermal interface material (STIM) placement by pick and place (P&P) equipment, which may be followed by a second flux spray onto the STIM surface by a flux dispenser. Prior to these operations, set-up procedures are conducted to ensure an accurate flux weight is dispensed by the flux dispenser. However, due to change in process conditions, flux viscosities, and micrometer setting stability issues, flux weight changes during lot processing, which may cause variations in the amount of flux dispensed and flux overspray onto the substrate and other components. In addition, the set up procedures for flux weight measurement require an additional 30 to 40 minutes per lot processing time which reduces efficiency.

Inaccurate flux measurements may cause STIM voiding, which commonly occurs at the bulk thermal interface material (TIM) or Die-STIM-Integrated heat spreader (IHS) interfaces. Such voiding is mainly due to flux amount and solvent loss causing high viscous residual flux, which causes material entrapment in the liquid STIM and residual flux material out gassing during a high temperature STIM reflow process. Thus, controlling liquid flux amount and coverage on the STIM prior to reflow process may reduce high voiding at the STIM-die-IHS interfaces.

### BRIEF DESCRIPTION OF THE DRAWINGS

FIG. 1 is a cross-sectional, schematic illustration of an electronic device adapted to accommodate a thermal interface in accordance with some embodiments.

FIG. 2 is a graph which illustrates a liquid POR flux viscosity as a function of temperature due to solvent loss in accordance with some embodiments.

FIG. 3 is a graph illustrating mean total void data between different die flux weights for a liquid POR flux spray process in accordance with some embodiments.

FIG. 4 is a CSAM image illustrating voids in a conventional flux spray process.

FIG. 5 is a schematic illustration of a preform coated with flux in accordance with some embodiments.

FIG. 6 is a CSAM image illustrating voids in a flux precoated preform process in accordance with some embodiments.

FIG. 7 is a flowchart illustrating operations in a method to form an integrated circuit apparatus, according to some embodiments.

FIG. 8 is a schematic illustration of a computing device in accordance with some embodiments.

### DETAILED DESCRIPTION

Described herein is a flux precoated solder preform for thermal interface materials which may be used in electronic system such as, e.g., computing systems. In the following description, numerous specific details are set forth to provide a thorough understanding of various embodiments. However, it will be understood by those skilled in the art that the various embodiments may be practiced without the specific details. In other instances, well-known methods, procedures, components, and circuits have not been illustrated or described in detail so as not to obscure the particular embodiments.

In some embodiments the thermal interfaces described herein may be implemented to transfer heat from surfaces of electronic components such as, e.g., integrated circuits (ICs). In alternate embodiments the thermal interfaces described herein may be implemented to transfer heat in any setting where heat is to be conducted from one surface to another. For ease of explanation, the example of cooling an IC will be described.

FIG. 1 is a cross-sectional, schematic illustration of an electronic device adapted to accommodate a thermal interface in accordance with some embodiments. Referring to FIG. 1, electronic device 100 includes an IC die 120 coupled to an upper surface of a substrate 110, such as a circuit board. Substrate 110 can be a one-layer circuit board or a multi-layer circuit board.

IC die 120 generates its heat from internal structure, including wiring traces. Heat generated by IC die 120 may be dissipated by a heat dissipation assembly 150. In some embodiments, heat dissipation assembly 150 may include a heat sink to dissipate heat into the ambient environment. The heat sink may be active, i.e., it may utilize one or more fans to dissipate heat, or passive, i.e., it may rely on convection to dissipate heat. In some embodiments, heat dissipation assembly 150 may include a heat pipe assembly that utilizes a fluid such as, e.g., water or oil, to dissipate heat generated by the integrated circuit die 120. The heat dissipation assembly 150 may, in one embodiment, include a “heat spreader.”

A thermal interface material 130 is disposed between the integrated circuit die 120 and the heat dissipation assembly 150 to establish a thermal pathway between the integrated circuit die 120 and the heat dissipation assembly 150. In some embodiments, thermal interface material 130 comprises at least one of an indium alloy, an indium-tin alloy, an indium-silver alloy, a boron-nitride compound, or a lead-tin alloy. Thermal interface material may include a polymer base such as, e.g., a grease, a gel, or a phase change material (PCM).

In some embodiments a barrier layer 140 may be disposed between the thermal interface material 130 and the heat dissipation assembly 150. Barrier layer 140 may be formed from a material such as, e.g., nickel, which inhibits intermetallic interaction between the heat dissipation assembly 150 and the thermal interface material 130. In some embodiments, barrier layer 140 may be formed as a separate structural element, which may be positioned between thermal interface material 130 and heat dissipation assembly 150. In some embodiments, barrier layer 140 may be coated onto a surface of either (or both) of thermal interface material 130 or heat dissipation assembly 150, e.g., by nickel plating, dipping, brushing, coating, or depositing a layer of nickel onto the surface.

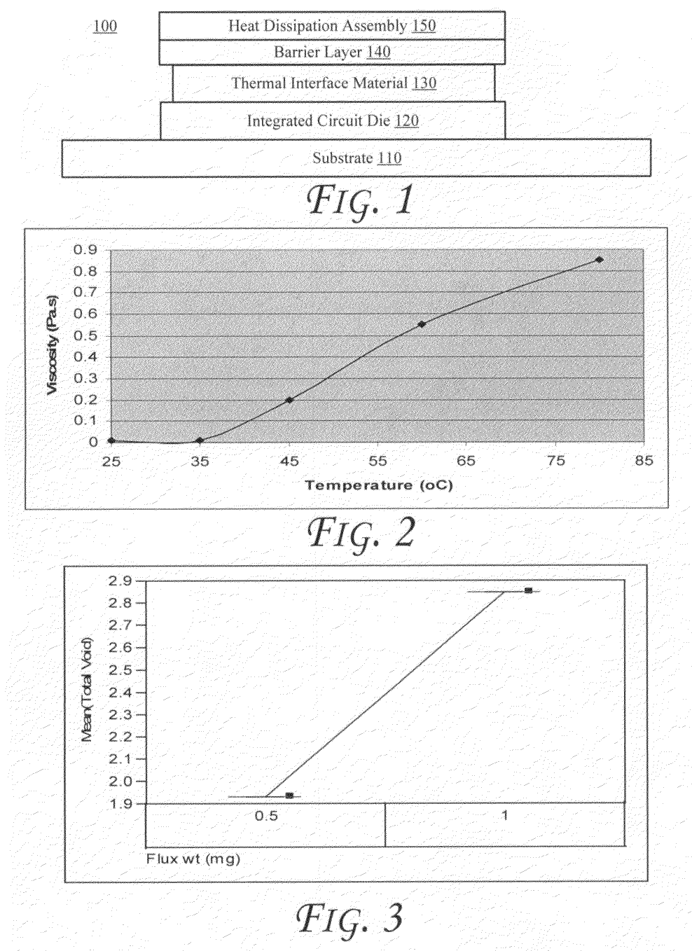

The subject matter described herein reduces solder TIM defects such as voiding, non wetting caused by three main factors. The first factor is non uniform flux spray on the die and solder TIM during process. When flux thickness is not uniform across the die and the solder TIM, thus, some areas may not be covered by flux, which may result in voiding and non wet during reflow due to poor fluxing activity in areas without flux coverage. The second factor is that flux solvent loss causes increased viscosity of residual flux material. For example, FIG. 2 is a graph which illustrates a liquid POR flux viscosity as a function of temperature due to solvent loss. Remaining viscous materials serve as a source of out-gassing which causes high voiding during reflow. In addition, high flux weight results in an increase in amount of residual flux material and higher voiding than low flux weight. FIG. 3 is a graph illustrating mean total void data between different die flux weights for a liquid POR flux spray process. The third factor is that residual material left after solvent loss is entrapped by the liquid solder TIM during the reflow process causing solder TIM non wet and voiding.

As described herein, the uniformity of flux thickness may be improved by apply thin coated flux (i.e., 0% to 50% solids) on an indium or any other solder TIM. Increasing the uniformity of flux thickness reduces flux coverage problems, and entrapment of residual flux material during reflow, which in turn reduces solder TIM defects.

In some embodiments, flux may be sprayed onto the backside of a die and the solder TIM. Using activated no clean flux or rosin mild activator (RMA) flux improves cleaning of the solder TIM oxide and interfacial IMC tarnishes formed prior to and during reflow. A fluxing reaction shown in Equation 1 may be thermally induced and fluxing activity is maximized at solder reflow temperature. Equation 1a indicates reaction of metal oxide with flux base component such as, e.g., abietic acid to form metal abietate such as, e.g., Indium-gold abietate (a base flux component undergoes isomeric transformations at different temperatures). Metal oxide is further reduced with flux activators as shown in equation 1b to prevent re-oxidation during reflow for maximum solder TIM defects reduction.

MOₙ+2nRCOOH→M(RCOO)ₙ+nH₂O (a)

MOₙ+2nHX→MXₙ+nH₂O (b) Equation 1

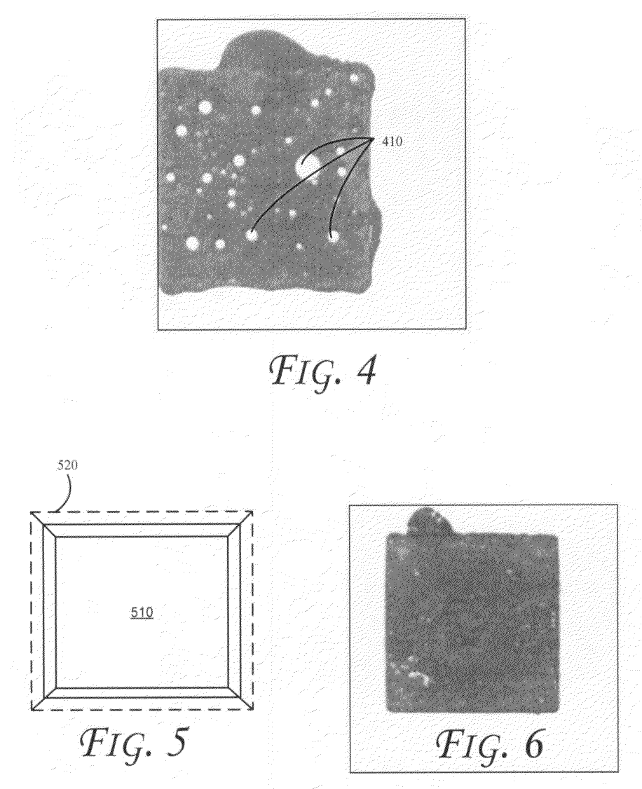

FIG. 4 is a CSAM image illustrating voids in a conventional flux spray process. Due to difficulty in achieving uniform flux spray onto the die and solder TIM preform as well as solvent loss resulting in high viscous solid content, and residual material entrapment that results in defects formations 410 of solder TIM during reflow.

FIG. 5 is a schematic illustration of a preform 510, which is coated with flux 520 in accordance with some embodiments. In some embodiments, a TIM preform may be pre-coated with a flux to reduce or eliminate defects such as solder TIM voiding. In some embodiments the flux composition for a pre-coated solder TIM may include a combination of the following acid activators, surfactants, rosin, solvent and rheological additives: activators containing di-carboxylic acids such as adipic and pimelic acids and covalent halide activators such as ethanol amine Hcl and dimethyl amine Hcl; and surfactants such as ethanol amines and ethoxylated amines for additional wettability; solvents such as glycol ethers and or aliphatic ethers and acetone for superior solvency action for rosin and activators and to improve rheological action on STIM during flux application; rosin, e.g., a composition of isomers of resin acids of C19H29COOH consisting of 3 rings with difference in position of the double bonds and the attached alkyl group. Isomeric transformations of rosin occurs at different temperatures during reflow; rheological additives include polyethylene glycol additives, and or ricinoleic acid and oleic acid for uniform coating of flux material on the STIM and release of flux material onto the die surface during STIM placement. These flux components may be selected based on their melting point, compatibility with other flux components, and their solubility in the solvent. In addition, a covalent halide activator amount (i.e., less than 1% of Cl- expressed as mass percent per rosin content) may improve wettability and clean the oxide layers on the STIM surface without causing excessive corrosion or reducing shelf life. Similarly, di-carboxylic acids and covalent halide activators maintain thermal stability at room temperature without causing excessive corrosion or reducing shelf life.

In some embodiments, flux coated STIM may include the following:

A: Flux solid contents: activators, rosin, surfactants and other additives that make up solid contents in the range (i.e. 0% to 50% by weight, with remaining material made up of solvents) to permit application of thin layers of flux on the TIM preform. This will ensure uniform monolayer of flux thickness on solder TIM and flexibility in amount of solids and solvents for any application irrespective of STIM thickness or size.

The added component can come from a group of slow evaporating solvents (a) propylene/ethylene glycol ethers and acetates, diethers (diglyme), (ex propylene glycol methyl ether, tripropylene glycol methyl ether, di-ethylene glycol n-butyl ether, dipropylene glycol methyl ether, ethylene glycol n-butyl ether, diethylene glycol n-butyl ether, diethylene glycol methyl ether), primary amyl acetate, cellosolve acetate, diisobutyl ketone, diacetone alcohol, butyl cellosolve, butyl cellosolve acetate, glycol diacetate, carbitol acetate, butyl carbitol acetate, (b) an azeotrope of the mixture of (a) with alcohols or other solvents for ex. butyl carbitol solvent & ethylene glycol.

Acid activators can come from a group of adipic acid, pimelic acid, citric acid, malonic acid, succinic acid, glutaric acid and others.

B: Rheological additives (including ethoxylated amines, ethanolamines surfactants and other additives such as polyethylene glycols derivatives, or ricinoleic acid and oleic acid) to improve easy flow, wettability and flux material coverage to the solder TIM preform after drying. This prevents dried (coated) flux material from cracking during solder TIM preform handling and during placement onto the die. The material also improves flux tackiness on the die and IHS lid after placement and sufficiently less tacky for TIM preform pick and place

C: Flux compositions melting temperatures: Linear di-carboxylic organic acids activators at low, medium and high temperatures (e.g., Pimelic acid, which has a melting point of 105 C; adipic acid, which has a melting point of 152 C; Succinic acid, which has a melting point of 187 C) and or covalent halide activators at low, medium and high melting temperatures (e.g., ethanolamine Hcl, which has a melting point of 84 C; di methylamine Hcl, which has a melting point of 170 C; and di ethylamine Hcl, which has a melting point of 227 C) for improved stability of activators at STIM soaking temperatures and melting temperatures for enhanced cleaning of Indium oxides and for non wet improvement for different category of solder TIM.

The amount of covalent halide activator (i.e., less than 1% of Cl-expressed as mass percent per rosin content) improves wettability and clean the oxide layers on the solder TIM surface and residual oxide layers on the intermetallics from base materials containing Au and Ni. The amount will not cause corrosion or other integrated shelf life issues since covalent halide is very stable at ambient temperature.

Due to isomeric transformations of rosin at different temperatures, selection of rosin temperatures depend on other flux components and solder TIM used. For example—Levopimaric acid C₂₀H₃₀O₂, which has a melting point of 150-152 C; Palustric C₂₀H₃₀O₂, which has a melting point of 162-167 C; Abietic C₂₀H₃₀O₂, which has a melting point of 172-175 C and Pimaric C₂₀H₃₀O₂, which has a melting point of 218-219 C. Rosin melting temperature may be selected to reduce flux entrapment in the solder TIM during reflow and for improved fluxing activity.

Solvents such as IPA, which has a melting point of 82 C, aliphatic ketone such as acetone, which has a melting point of 55-65 C; and glycol ether of which has a melting point of 140-220 C to provide superior solvency action for rosin, activators and other flux additives for a balanced viscosity prior to flux application on the preform.

Table 1 illustrates various Solder alloy compositions which may be used in flux precoated TIM.

TABLE 1

| | Melting Temp |
|---|---|
| Alloy Type | (° C.) |
| In | 157 |
| Sn | 232 |
| In—Sn | Variable |
| Au—Sn | 280 |
| Bi—Sn | 138 |
| Bi—In | 109 |
| Bi—Sn—Fe | 137 |
| In Ag | Variable |
| Sn—Ag | 221 |
| Sn—Cu | 227 |
| Bi—In—Sn | Variable |
| Sn—Ag—Cu | 216 |
| Sn—Ag—Cu—Sb | 217 |
| Sn—Bi—Ag | 211 |
| Sn—Ag—Sb | 233 |
| Sn—Bi—Ag—Cu | 210 |
| Sn—Ag—Zn | 217 |
| Sn—Ag—Zn—Cu | Variable |
| Sn—Cd | 177 |
| Sn—Bi—Cu—Ag | Variable |
| Sn—Bi—Cu—Ag—P | Variable |
| Bi—Sb | 308 |
| Sn—Cu—Ag | 260 |
| Sn—Cu—Sb—Ag | 256 |
| Sn—In | Variable |
| Sn—In—Ag | 187 |
| Sn—In—Ag—Sb | 211 |
| Sn—Cu—Ag—Sb | 211 |
| Sn—In—Bi | Variable |
| Sn—In—Bi—Ag | Variable |
| Sn—Sb | 240 |
| Sn—Sb—Bi Ag | Variable |
| Sn—Zn | 199 |
| Sn—Zn—In | 188 |
| Sn—Zn—In—Ag | Variable |
| Sn—Zn—In—Cu | Variable |

FIG. 6 is a CSAM image illustrating voids in a flux spray process in accordance with some embodiments. Referring to FIG. 6, the solder pre-form results in improved flux coverage on the surface of the preform.

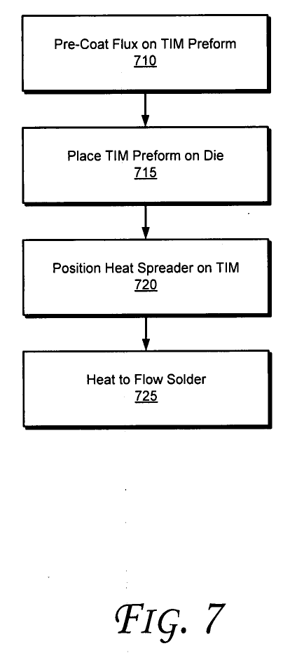

FIG. 7 is a flowchart illustrating operations in a method to form an integrated circuit apparatus, according to some embodiments. Referring to FIG. 7, at operation 710 solder is pre-coated on a TIM preform. In some embodiments the solder may include a flux as described above. At operation 715 the TIM preform is placed on a die, e.g., an integrated circuit die 120 as depicted in FIG. 1. At operation 720 a heat sink, e.g., a heat dissipation assembly 150 is positioned on the TIM. In some embodiments a barrier layer 140 may be interposed between the TIM and the head spreader. At operation 725 the apparatus is heated to flow the solder, which secures the assembly.

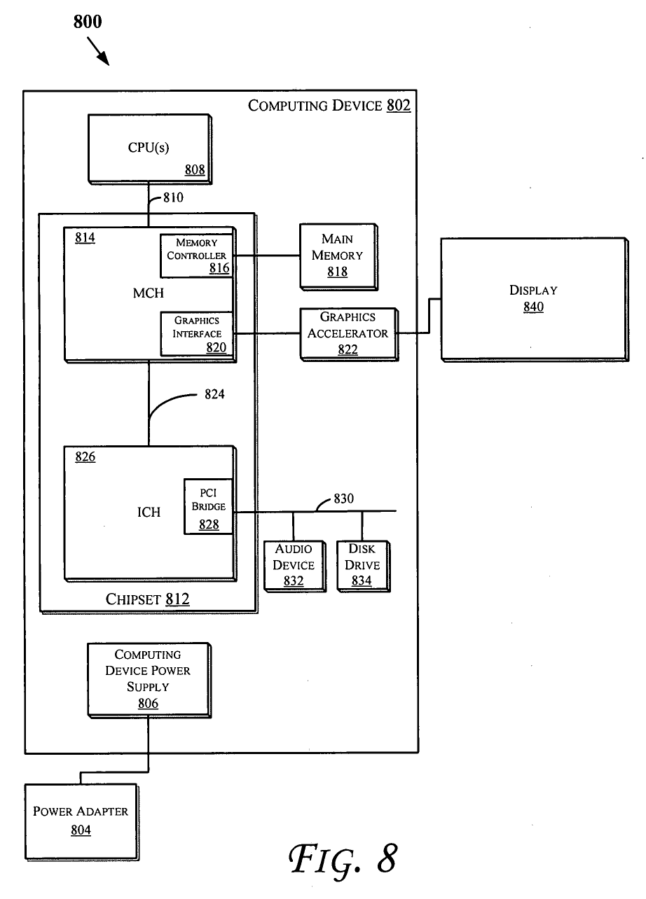

FIG. 8 is a schematic illustration of a computer system 800 in accordance with an embodiment. The computer system 800 includes a computing device 802 and a power adapter 804 (e.g., to supply electrical power to the computing device 802). The computing device 802 may be any suitable computing device such as a laptop (or notebook) computer, a personal digital assistant, a desktop computing device (e.g., a workstation or a desktop computer), a rack-mounted computing device, and the like.

Electrical power may be provided to various components of the computing device 802 (e.g., through a computing device power supply 806) from one or more of the following sources: one or more battery packs, an alternating current (AC) outlet (e.g., through a transformer and/or adaptor such as a power adapter 804), automotive power supplies, airplane power supplies, and the like. In one embodiment, the power adapter 804 may transform the power supply source output (e.g., the AC outlet voltage of about 110VAC to 240VAC) to a direct current (DC) voltage ranging between about 8VDC to 12.6VDC. Accordingly, the power adapter 804 may be an AC/DC adapter.

The computing device 802 may also include one or more central processing unit(s) (CPUs) 808 coupled to a bus 810. In one embodiment, the CPU 808 may be one or more processors in the Pentium® family of processors including the Pentium® II processor family, Pentium® III processors, Pentium® IV processors available from Intel® Corporation of Santa Clara, Calif. Alternatively, other CPUs may be used, such as Intel's Itanium®, XEON™, and Celeron® processors. Also, one or more processors from other manufactures may be utilized. Moreover, the processors may have a single or multi core design.

A chipset 812 may be coupled to the bus 810. The chipset 812 may include a memory control hub (MCH) 814. The MCH 814 may include a memory controller 816 that is coupled to a main system memory 818. The main system memory 818 stores data and sequences of instructions that are executed by the CPU 808, or any other device included in the system 800. In one embodiment, the main system memory 818 includes random access memory (RAM); however, the main system memory 818 may be implemented using other memory types such as dynamic RAM (DRAM), synchronous DRAM (SDRAM), and the like. Additional devices may also be coupled to the bus 810, such as multiple CPUs and/or multiple system memories.

The MCH 814 may also include a graphics interface 820 coupled to a graphics accelerator 822. In one embodiment, the graphics interface 820 is coupled to the graphics accelerator 822 via an accelerated graphics port (AGP). In an embodiment, a display (such as a flat panel display) 840 may be coupled to the graphics interface 820 through, for example, a signal converter that translates a digital representation of an image stored in a storage device such as video memory or system memory into display signals that are interpreted and displayed by the display. The display 840 signals produced by the display device may pass through various control devices before being interpreted by and subsequently displayed on the display.

A hub interface 824 couples the MCH 814 to an input/output control hub (ICH) 826. The ICH 826 provides an interface to input/output (I/O) devices coupled to the computer system 800. The ICH 826 may be coupled to a peripheral component interconnect (PCI) bus. Hence, the ICH 826 includes a PCI bridge 828 that provides an interface to a PCI bus 830. The PCI bridge 828 provides a data path between the CPU 808 and peripheral devices. Additionally, other types of I/O interconnect topologies may be utilized such as the PCI Express™ architecture, available through Intel® Corporation of Santa Clara, Calif.

The PCI bus 830 may be coupled to an audio device 832 and one or more disk drive(s) 834. Other devices may be coupled to the PCI bus 830. In addition, the CPU 808 and the MCH 814 may be combined to form a single chip. Furthermore, the graphics accelerator 822 may be included within the MCH 814 in other embodiments.

Additionally, other peripherals coupled to the ICH 826 may include, in various embodiments, integrated drive electronics (IDE) or small computer system interface (SCSI) hard drive(s), universal serial bus (USB) port(s), a keyboard, a mouse, parallel port(s), serial port(s), floppy disk drive(s), digital output support (e.g., digital video interface (DVI)), and the like. Hence, the computing device 802 may include volatile and/or nonvolatile memory.

In the description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one embodiment” “some embodiments” or “an embodiment” means that a particular feature, structure, or characteristic described in connection with the embodiment is included in at least an implementation. The appearances of the phrase “in one embodiment” in various places in the specification may or may not be all referring to the same embodiment.

Although embodiments have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. An apparatus, comprising:
a semiconductor device;
a heat dissipation assembly; and
a thermal interface material disposed between the semiconductor device and the heat dissipation assembly, wherein the thermal interface layer comprises a pre-coated flux material.

2. The apparatus of claim 1, wherein the thermal interface material comprises indium.

3. The apparatus of claim 1, wherein the flux material comprises a combination of acid activators, surfactants, rosin, solvent and rheological additives.

4. The apparatus of claim 3, wherein the surfactants acid activators comprise at least one of adipic and pimelic acids and covalent halide activators such as ethanol amine Hcl and dimethyl amine Hcl.

5. The apparatus of claim 3, wherein the surfactants comprise at least one of ethanol amines and ethoxylated amines.

6. The apparatus of claim 3, wherein the solvent comprises a composition of isomers of resin acids of C₁₉H₂₉COOH consisting of 3 rings with a difference in position of the double bonds and the attached alkyl group.

7. The apparatus of claim 3, wherein the rheological additives comprises at least one of polyethylene glycol additives, and or ricinoleic acid and oleic acid.

8. A system, comprising:
a processor coupled to a printed circuit board;
a semiconductor device;
a heat dissipation assembly; and
a thermal interface material disposed between the semiconductor device and the heat dissipation assembly, wherein the thermal interface layer comprises a pre-coated flux material.

9. The system of claim 8, wherein the thermal interface material comprises indium.

10. The system of claim 8, wherein the flux material comprises a combination of acid activators, surfactants, rosin, solvent and rheological additives.

11. The system of claim 10, wherein the surfactants acid activators comprise at least one of adipic and pimelic acids and covalent halide activators such as ethanol amine Hcl and dimethyl amine Hcl.

12. The system of claim 10, wherein the surfactants comprise at least one of ethanol amines and ethoxylated amines.

13. The system of claim 10, wherein the solvent comprises a composition of isomers of resin acids of C₁₉H₂₉COOH consisting of 3 rings with a difference in position of the double bonds and the attached alkyl group.

14. The system of claim 10, wherein the rheological additives comprises at least one of polyethylene glycol additives, and or ricinoleic acid and oleic acid.
